(19) United States
(12) Patent Application Publication
(10) Pub. No.: US 2010/0107033 A1
(43) Pub. Date: Apr. 29, 2010

(54) RADIO COMMUNICATION DEVICE AND PUNCTURING METHOD

(76) Inventors: Kenichi Kuri, Kanagawa (JP); Akihiko Nishio, Kanagawa (JP)

Correspondence Address: Dickinson Wright PLLC;James E. Ledbetter, Esq., International Square, 1875 Eye Street, N.W., Suite 1200, Washington, DC, 20006, US

(21) Appl. No.: 12/524,680

(22) PCT Filed: Jan. 30, 2008
(86) PCT No.: PCT/JP2008/051383

§ 371 Date: Jul. 27, 2009

(30) Foreign Application Priority Data
Jan. 31, 2007 (JP) 2007-022031

(51) Int. Cl. H03M 13/05; G06F 11/10

(52) U.S. Cl. 714/752; 714/790; 714/E11.032

(57) ABSTRACT

Provided is a radio communication device which can minimize degradation of the error ratio characteristic attributed to puncturing when an LDPC code is used as an error correction code. In this device, an LDPC encoding unit (101) performs LDPC encoding on a transmission bit string by using an inspection matrix and obtains an LDPC code word formed by a systematic bit and a parity bit. The LDPC code word is outputted to a puncturing unit (102). Moreover, the LDPC encoding unit (101) outputs the inspection matrix to the puncturing unit (102). The puncturing unit (102) performs puncturing on the parity bits in the LDPC code word in ascending order of the inspection matrix column weight and if there are a plurality of parity bits having the same column weight, in the descending order of the inspection matrix row weight of the check node connected to variable nodes corresponding to the parity bits and outputs the LDPC code word after the puncturing to a modulation unit (103).

### TECHNICAL FIELD

The present invention relates to a radio communication apparatus and puncturing method.

### BACKGROUND ART

In recent years, multimedia communication such as data communication and video communication has continued to increase in popularity. Therefore, data sizes are expected to increase even more in the future, and growing demands for higher-speed data rates for mobile communication services are also anticipated.

To realize future ultra high speed transmission, an LDPC (Low-Density Parity-Check) code has attracted attention as an error correcting code. Use of an LDPC code as an error correcting code enables decoding processing to be parallelized, allowing decoding processing to be speeded up compared with the use of a turbo code that requires iterative serial execution of decoding processing.

LDPC encoding is performed using a parity check matrix where a large number of 0s and a small number of 1s are arranged. A radio communication apparatus of the transmitting side encodes a transmission bit sequence using a parity check matrix, to obtain an LDPC codeword composed of systematic bits and parity bits. A radio communication apparatus of the receiving side decodes received data by iteratively executing passing of the likelihoods of individual bits between the parity check matrix row direction and the parity check matrix column direction, to acquire a received bit sequence. Here, the number of 1s contained in each column in a parity check matrix is called the column degree, and the number of 1s contained in each row in a parity check matrix is called the row degree. A parity check matrix can be represented by a Tanner graph, which is a two-part graph composed of rows and columns. In a Tanner graph, each row of a parity check matrix is called a check node, and each column of a parity check matrix is called a variable node. Variable nodes and check nodes of a Tanner graph are connected in accordance with the arrangement of Is in the parity check matrix, and a radio communication apparatus of the receiving side decodes received data by iteratively executing passing of likelihoods between connected nodes, to obtain a received bit sequence.

A method of setting a higher coding rate than a coding rate of the LDPC code (hereinafter referred to as “mother coding rate”) is the puncturing. The puncturing is a technique of removing specific bits of a codeword. This enables a higher coding rate than the mother coding rate to be set.

As a conventional puncturing technique for the LDPC codeword, puncturing parity bits in ascending order of the column degree is studied (see Patent Document 1).

### Patent Document 1: Japanese Patent Application Laid-Open No. 2006-54575

### DISCLOSURE OF INVENTION

### Problems to be Solved by the Invention

However, in the above conventional technique, there has been little study of which parity bit to start puncturing from in the case where there are a plurality of parity bits having the same column degree. In LDPC coding, error rate performances vary based on the size of a row degree as well as based on the size of a column degree. Consequently, error rate performances may degrade if puncturing is performed focusing only on column degree alone as in the above conventional technique.

It is therefore an object of the present invention to provide a radio communication apparatus and a puncturing method that can minimize the degradation of error rate performances due to puncturing when LDPC code is used as error correcting code.

### Means for Solving the Problem

The radio communication apparatus of the present invention adopts the configuration including: an encoding section that performs low density parity check encoding for a transmission bit sequence using a parity check matrix, to acquire a codeword composed of systematic bits and parity bits; and a puncturing section that punctures, in the codeword, the parity bits in order from a parity bit of a smallest column degree in the parity check matrix, and, when there are a plurality of parity bits of a same column degree, punctures the parity bits in order from the parity bit corresponding to a variable node connected with a check node of a largest row degree in the parity check matrix.

### ADVANTAGEOUS EFFECTS OF INVENTION

According to the present invention, it is possible to minimize the degradation of error rate performances due to puncturing when LDPC code is used as error correcting code.

### BRIEF DESCRIPTION OF DRAWINGS

FIG. 1 is a block diagram showing a configuration of the radio communication apparatus of the transmitting side according to Embodiment 1 of the present invention;

FIG. 2 is a parity check matrix according to Embodiment 1 of the present invention;

FIG. 3 is a Tanner graph according to Embodiment 1 of the present invention;

FIG. 4 illustrates puncturing processing according to Embodiment 1 of the present invention;

FIG. 5 is a block diagram showing a configuration of the radio communication apparatus of the receiving side according to Embodiment 1 of the present invention;

FIG. 6 illustrates padding processing according to Embodiment 1 of the present invention;

FIG. 7 is a parity check matrix according to Embodiment 2 of the present invention;

FIG. 8 is a Tanner graph according to Embodiment 2 of the present invention; and

FIG. 9 illustrates puncturing processing according to Embodiment 2 of the present invention.

### BEST MODE FOR CARRYING OUT THE INVENTION

Now, embodiments of the present invention will be described in detail with reference to the accompanying drawings.

In the following description, parts in the columns in a parity check matrix or amongst variable nodes in a Tanner graph corresponding to parity bits, will be called “parity bit positions,”

### Embodiment 1

In the present embodiment, in the case where there are a plurality of parity bits having the same column degree of a parity check matrix, parity bits are punctured in order from the parity bit corresponding to the variable node connected with the check node having the largest row degree of the parity check matrix.

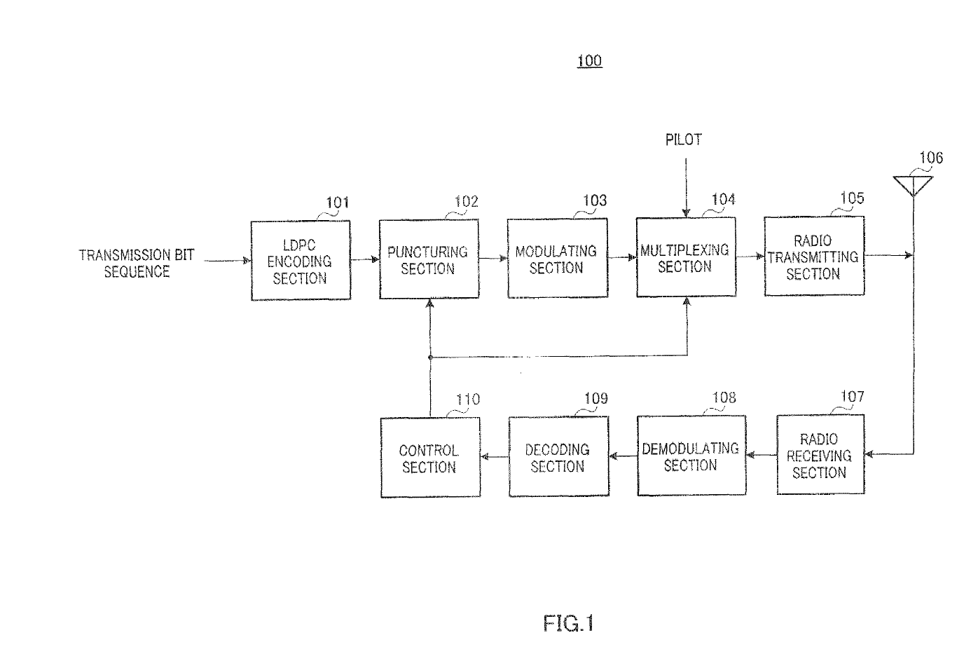

FIG. 1 shows the configuration of radio communication apparatus 100 of the transmitting side according to the present embodiment.

In radio communication apparatus 100 of the transmitting side, LDPC encoding section 101 receives a transmission bit sequence as input. LDPC encoding section 101 performs LDPC encoding on the transmission bit sequence using a parity check matrix to acquire a LDPC codeword formed with systematic bits and parity bits. This LDPC codeword is outputted to puncturing section 102. Further, LDPC encoding section 101 outputs a parity check matrix to puncturing section 102.

Puncturing section 102 punctures the parity bits in the LDPC codeword, and outputs the LDPC codeword after puncturing to modulating section 103. The number of parity bits to puncture is determined based on the difference between the coding rate in LDPC encoding section 101 (i.e. the mother coding rate) and the coding rate set up from control section 110 (i.e. the coding rate of the LDPC codeword after puncturing). To be more specific, the number of parity bits to puncture is determined by N(1−(Rₘ/R)). Here, N represents the LDPC codeword length, Rₘ represents the mother coding rate and R represents the coding rate received as input from control section 110. The puncturing processing in puncturing section 102 will be described later in detail.

Modulating section 103 generates data symbols by modulating the LDPC codeword after puncturing, and outputs the generated data symbols to multiplexing section 104.

Multiplexing section 104 multiplexes the data symbols, pilot signals and control signals received as input from control section 110, and outputs the generated multiplexed signal to radio transmitting section 105.

Radio transmitting section 105 performs transmitting processing including D/A conversion, amplification and up-conversion on the multiplexed signal, and transmits the signal after transmitting processing to a radio communication apparatus of the receiving side from antenna 106.

Meanwhile, radio receiving section 107 receives the control signal transmitted from the radio communication apparatus of the receiving side through antenna 106, performs receiving processing such as down-conversion and A/D conversion on the control signal and outputs the control signal after receiving processing, to demodulating section 108. This control signal includes a CQI (Channel Quality Indicator) generated in the radio communication apparatus of the receiving side.

Demodulating section 108 demodulates the control signal and outputs the demodulated signal to decoding section 109.

Decoding section 109 decodes the control signal and outputs the CQI included in the control signal to control section 110.

Control section 110 controls the coding rate of the LDPC codeword after puncturing, according to the CQI. Control section 110 determines a coding rate corresponding to the CQI received as input, and outputs a control signal showing the determined coding rate to puncturing section 102 and multiplexing section 104. When the CQI received as input corresponds to higher channel quality, control section 110 determines the coding rate of the LDPC codeword after puncturing to be a higher coding rate.

Next, the puncturing processing in puncturing section 102 will be described in detail.

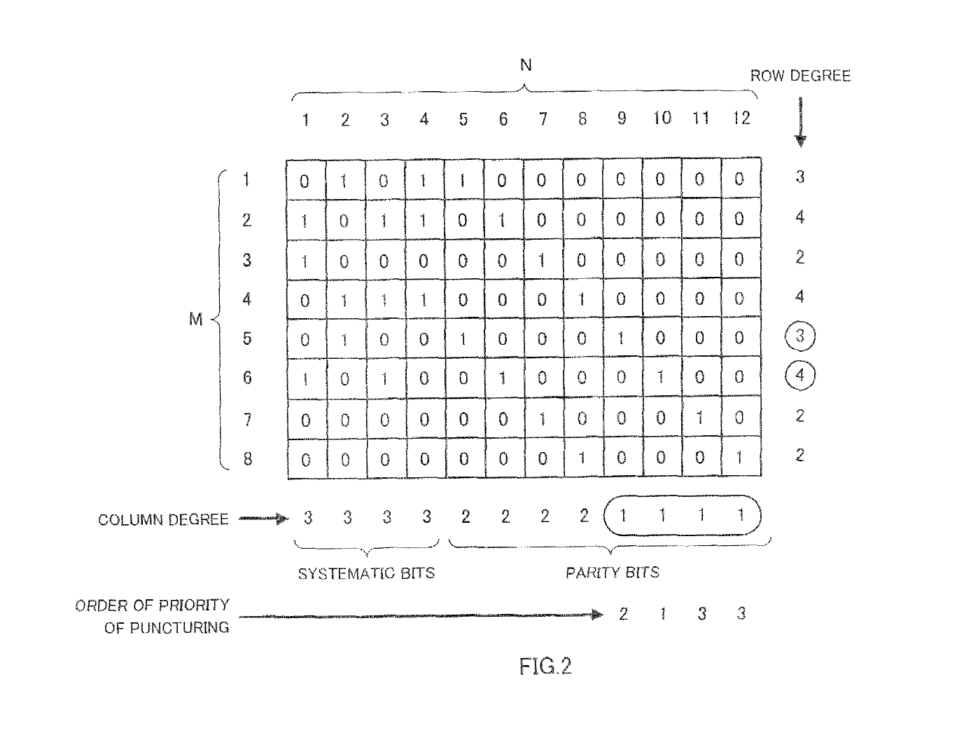

FIG. 2 shows an 8×12 parity check matrix as an example. As shown here, a parity cheek matrix is represented by a M×N matrix and is composed of 0s and 1s.

Each column in a parity check matrix corresponds to bits in the LDPC codeword. That is, when LDPC encoding is performed using the parity check matrix shown in FIG. 2, a 12-bit LDPC codeword is acquired.

Further, in the parity check matrix shown in FIG. 2, the column degree of the first column is the number of 1s in the first column, that is, three, and the column degree of the second column is the number of 1s in the second column, that is, three. Therefore, in the 12-bit LDPC codeword, the column degree of the first bit is three and the column degree of the second bit is three. The same will apply to the third to twelfth column.

Likewise, in the parity check matrix shown in FIG. 2, the row degree of the first row is the number of is in the first row, that is, three, and the row degree of the second row is the number of 1s in the second row, that is, four. The same will apply to the third to the eighth row.

Furthermore, the parity check matrix shown in FIG. 2 can be represented by a Tanner graph composed of the rows and columns of the parity check matrix.

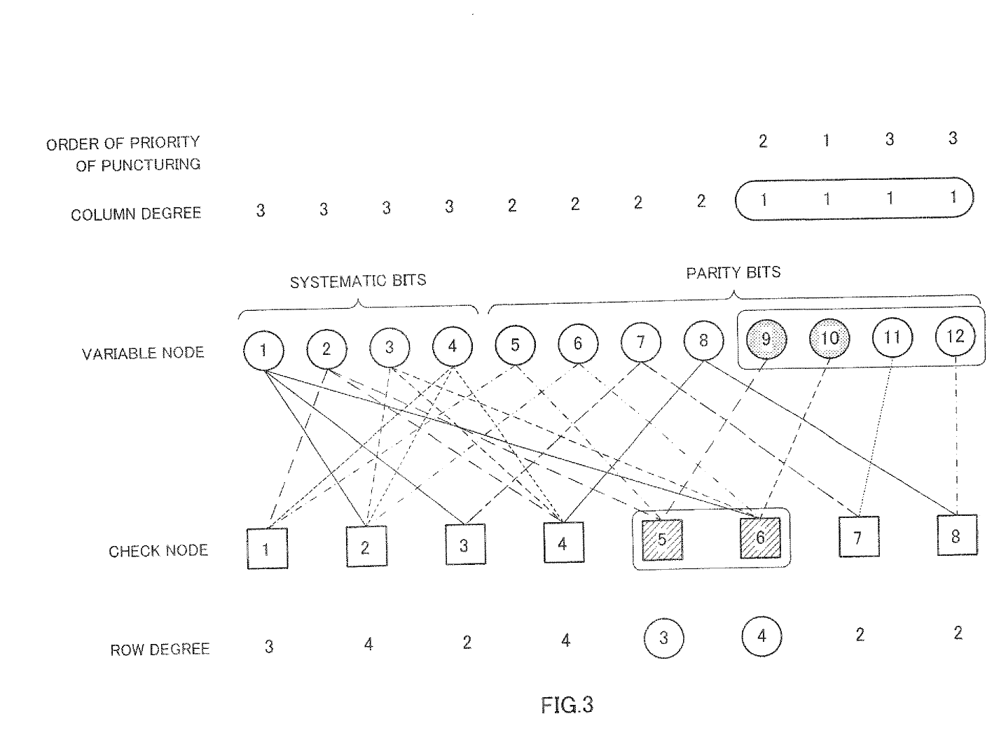

FIG. 3 shows a Tanner graph corresponding to the parity cheek matrix in FIG. 2. The Tanner graph is composed of check nodes corresponding to rows of a parity check matrix and variable nodes corresponding to columns of a parity check matrix. That is, the Tanner graph corresponding to an 8×12 parity check matrix is a two-part graph composed of eight check nodes and twelve variable nodes.

Furthermore, variable nodes in the Tanner graph correspond to bits in the LDPC codeword.

Here, the variable nodes and check nodes in the Tanner graph are connected in accordance with the arrangement of “1”s in the parity check matrix.

Specific explanation will be given based on the variable nodes. Variable node 1 in the Tanner graph shown in FIG. 3 corresponds to the first column (N=1) of the parity check matrix shown in FIG. 2. The column degree of the first column of the parity check matrix is three, and the rows in which a 1 is located in the first column are the second row, third row and sixth row.

Therefore, there are three connections from variable node 1, that is, check node 2, check node 3 and check node 6. Likewise, variable node 2 in the Tanner graph corresponds to the second column (N=2) of the parity check matrix. The column degree of the second column of the parity check matrix is three, and the rows in which a 1 is located in the second column are the first row, fourth row and fifth row. Therefore, there are three connections from variable node 2, that is, check node 1, check node 4 and check node 5. The same will apply to variable node 3 to variable node 12.

Similarly, to give a concrete description based on check nodes, check node 1 of the Tanner graph shown in FIG. 3 corresponds to the first row (M=1) of the parity check matrix shown in FIG. 2. The row degree of the first row of the parity check matrix is three, and the columns in which a 1 is located in the first row are the second column, fourth column and fifth column. Therefore, there are three connections from check node 1, that is, variable node 2, variable node 4 and variable node 5. Likewise, check node 2 in the Tanner graph corresponds to the second row (M=2) of the parity check matrix. The row degree of the second row of the parity check matrix is four, and the column in which a 1 is located in the second row is the first column, third column, fourth column and sixth column. Therefore, there are four connections from check node 2, that is, for variable node 1, variable node 3, variable node 4 and variable node 6. The same applies to check node 3 to check node 8.

In this way, in a Tanner graph, the variable nodes and check nodes are connected in accordance with the arrangement of 1s in a parity check matrix. That is, the number of check nodes connected to each variable node in a Tanner graph equals the column degree of a column in a parity check matrix. Also, the check nodes with which each variable node is connected in a Tanner graph are the check nodes corresponding to the rows in which 1s are located in the columns in a parity check matrix. Likewise, the number of variable nodes connected to each check node in a Tanner graph equals the row degree of a row in a parity check matrix. Also, the variable nodes with which each check node is connected in a Tanner graph are the variable nodes corresponding to the column in which 1s are located in the rows in a parity check matrix.

The radio communication apparatus of the receiving side passes likelihoods between the variable nodes, through the check nodes, and decodes received data by iteratively updating the likelihoods of the variable nodes. By this means, the number of times to pass likelihoods between variable nodes increases when a check node has a larger number of connections with variable nodes (i.e. when a check node having a larger row degree).

Further, when part of variable nodes are punctured and the number of variable nodes decreases, the ratio between the number of variable nodes to puncture and the number of variable nodes connected before puncturing is low at a check node having a larger number of connections with variable nodes, and therefore the degradation by puncturing of the effect of updating likelihoods is less.

Then, in the case where there are a plurality of parity bits having the same column degree in a LDPC codeword, puncturing section 102 punctures the parity bits in order from the parity bit corresponding to the variable node connected with the check node holding connections with the largest number of variable nodes, that is, in order from the parity bit corresponding to the variable node connected with the check node having the largest row degree.

Now, a specific explanation will be given below. In the following explanation, the transmission bit sequence length is four bits and the mother coding rate Rₘ is ⅓. Further, the coding rate R determined in control section 110 is ⅖. Consequently, when LDPC encoding is performed on a 4-bit transmission sequence using the parity check matrix shown in FIG. 2, N=12-bit LDPC codeword composed of four systematic bits and eight parity bits is acquired. Further, puncturing section 102 derives the number of parity bits to puncture from N(1−(Rₘ/R)) and punctures two parity bits.

First, puncturing section 102 extracts the parity bits to be punctured candidates in order from the parity bit corresponding to the variable node having the smallest column degree in the parity check matrix (i.e. the parity bit corresponding to the variable node holding connections with the smallest number of check nodes). That is, puncturing section 102 extracts the ninth to twelfth column (variable node 9 to variable node 12 in the Tanner graph shown in FIG. 3) which have the smallest column degree, 1, and which have the same column degree, as punctured candidates, amongst the fifth to twelfth column corresponding to the parity bits in the parity check matrix shown in FIG. 2 (variable node 5 to variable node 12).

However, the number of parity bits to puncture in puncturing section 102 is two, while the number of columns to extract (the number of variable nodes holding connections with the same number of check nodes) is four, as shown in FIG. 2.

Then, puncturing section 102 extracts the parity bits to be punctured candidates in order from the parity bit corresponding to the variable node connected with the check node having the largest row degree in the parity check matrix (i.e. the parity bit corresponding to the variable node connected with the check node holding connections with the largest number of variable nodes).

That is, puncturing section 102 compares the row degrees of the rows in which 1s are located amongst the ninth to twelfth column in the parity check matrix shown in FIG. 2. That is, puncturing section 102 compares row degree 3 of the fifth row in which a 1 is located in the ninth column (i.e. the number of connections, 3, with variable nodes in check node 5 which variable node 9 is connected with), row degree 4 of the sixth row in which a 1 is located in the tenth column (i.e. the number of connections, 4, with variable nodes in check node 6 which variable node 10 is connected with), row degree 2 of the seventh row in which a 1 is located in the eleventh column (i.e. the number of connections, 2, with variable nodes in check node 7 which variable node 11 is connected with), and row degree 2 of the eighth row in which a 1 is located in the twelfth column (i.e. the number of connections, 2, with variable nodes in check node 8 which variable node 12 is connected with). That is, puncturing section 102 compares the number of connections with variable nodes between check nodes connected with each variable node amongst variable node 9 to variable node 12 in the Tanner graph shown in FIG. 3. Then, puncturing section 102 extracts the parity bits to be punctured candidates in order from the column corresponding to the largest row degree (i.e. from the variable node connected with the check node holding connections with the largest number of variable nodes).

Consequently, the order of priority in puncturing amongst the ninth to twelfth column (variable node 9 to variable node 12) is that, as shown in FIG. 2, the tenth column (variable node 10) is the first, the ninth column (variable node 9) the second, the eleventh column (variable node 11) and twelfth column (variable node 12) the third.

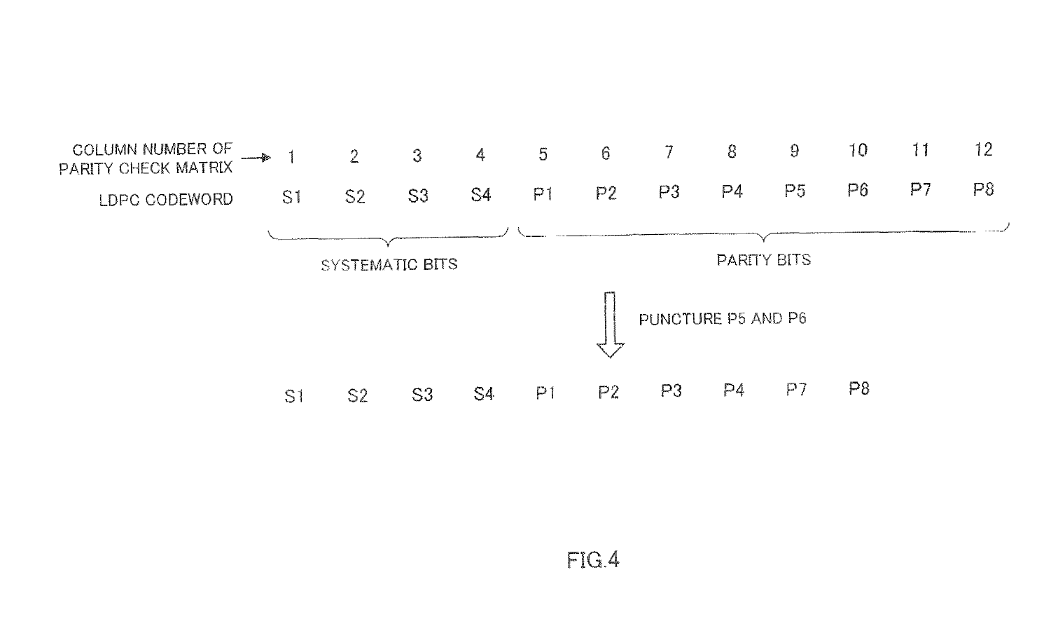

Then, given that the number of parity bits to puncture is two, puncturing section 102 punctures parity bit P6 in the tenth column (variable node 10) and parity bit P5 in the ninth column (variable node 9) in a 12-bit LDPC codeword composed of four systematic bits of S1 to S4 and eight parity bits of P1 to P8, as shown in FIG. 4, according to the order of priority of puncturing. By this means, puncturing section 102 can obtain a 10-bit LDPC codeword composed of four systematic bits of S1 to S4 and six parity bits of P1, P2, P3, P4, P7 and P8.

In this way, according to the present embodiment, in a case where there are a plurality of parity bits having the same column degree in a parity check matrix, parity bits are punctured in order from the parity bit corresponding to the variable node connected with the check node having the largest row degree in the parity check matrix. For this reason, the ratio between the number of variable nodes to puncture and the number of variable nodes connected via the check nodes before puncturing is low, so that it is possible to minimize the degradation of effect of updating likelihoods. Therefore, it is possible to perform LDPC encoding that minimizes the degradation of error rate performances due to puncturing.

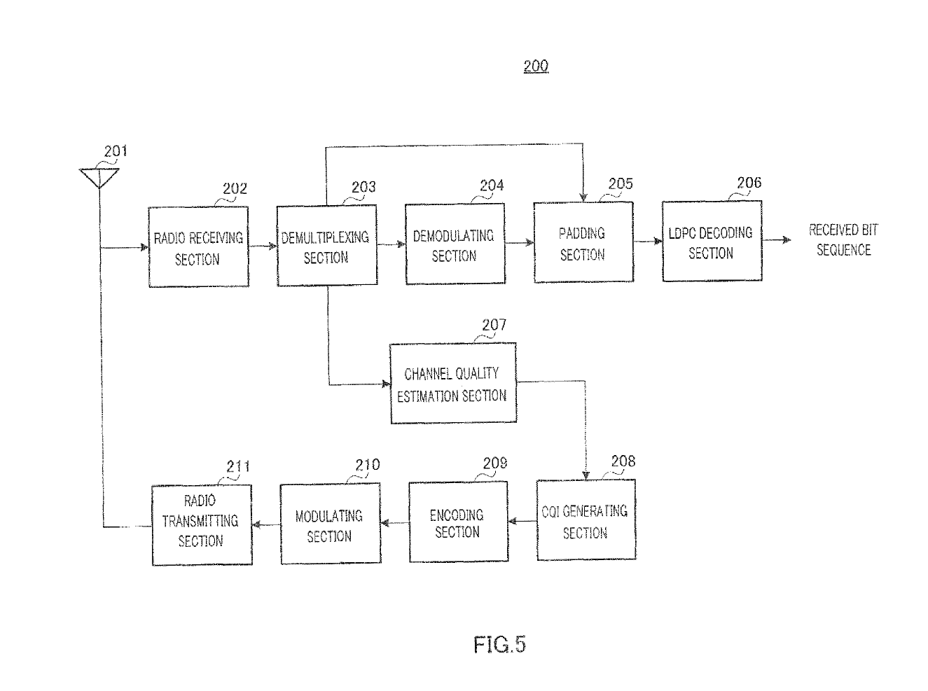

Next, the radio communication apparatus of the receiving side according to the present embodiment will be described. FIG. 5 shows the configuration of radio communication apparatus 200 of the receiving side according to the present embodiment.

In radio communication apparatus 200 of the receiving side, radio receiving section 202 receives a multiplexed signal transmitted from radio communication apparatus 100 (FIG. 1) of the transmitting side through antenna 201, performs receiving processing including down-conversion and A/D conversion on the received signal and outputs the signal subjected to receiving processing to demultiplexing section 203. This received signal includes data symbols, pilot signals and control signals that designate the coding rates determined in radio communication apparatus 100 of the transmitting side.

Demultiplexing section 203 demultiplexes the received signal into the data symbols, pilot signals and control signals. Then, demultiplexing section 203 outputs the data symbols to demodulating section 204, the pilot signals to channel quality estimation section 207 and the control signals to padding section 205.

Demodulating section 204 demodulates the data symbols to acquire received data and outputs the received data to padding section 205.

In the received data, padding section 205 pads padding bits of the logarithm of the likelihood ratio, 0, and outputs the acquired received data to LDPC decoding section 206. Further, the number of padding bits to pad is determined based on the difference between the coding rate in LDPC decoding section 206, that is, the coding rate Rₘ in LDPC encoding section 101 (FIG. 1) (i.e. the mother coding rate) and the coding rate R shown by the control signal received as input from demultiplexing section 203 (i.e. coding rate determined in control section 110 (FIG. 1)). To be more specific, the number of padding bits to pad is determined by Nᵣ((R/Rₘ)−1). Here, Nᵣ represents the data length of received data. That is, the number of padding bits to pad equals the number of parity bits to puncture in radio communication apparatus 100 (FIG. 1) of the transmitting side. The padding processing in padding section 205 will be described later in detail.

LDPC decoding section 206 performs LDPC decoding on the received data received as input from padding section 205 to acquire a received bit sequence, using the same parity check matrix as the parity check matrix used in LDPC encoding section 101 (FIG. 1).

Meanwhile, channel quality estimation section 207 estimates channel quality using the pilot signal received as input from demultiplexing section 203. Here, channel quality estimation section 207 estimates the SINR (Signal to Interference and Noise Ratio) of the pilot signal as channel quality, and outputs the estimated SINR to CQI generating section 208.

CQI generating section 208 generates a CQI corresponding to the SINR received as input, and outputs the generated CQI to encoding section 209.

Encoding section 209 encodes the CQI and outputs the encoded CQI to modulating section 210.

Modulating section 210 modulates the CQI to generate a control signal, and outputs the generated control signal to radio transmitting section 211.

Radio transmitting section 211 performs transmitting processing including D/A conversion, amplification and up-conversion on the control signal and transmits the signal after transmitting processing to radio communication apparatus 100 (FIG. 1) of the transmitting side from antenna 201.

Next, the padding processing in padding section 205 will be described in detail.

Similar to puncturing section 102 (FIG. 1) of radio communication apparatus 100 of the transmitting side, in the case where a plurality of parity bit positions having the same column degree in received data, padding section 205 pads padding bits in order from the same position as the parity bit position corresponding to the variable node connected with the check node having the largest row degree (i.e. the check node holding connections with the largest number of the variable nodes).

Here, the received data length Nᵣ is ten bits, the coding rate R represented by a control signal received as input from demultiplexing section 203 is ⅖, and the mother coding rate Rₘ is ⅓, so that padding section 205 determines the number of padding bits to pad from Nᵣ((R/Rₘ)−1) and pads two padding bits.

Similar to puncturing section 102 (FIG. 1), padding section 205 extracts the ninth to twelfth column (variable node 9 to variable node 12 in the Tanner graph shown in FIG. 3) which have the smallest column degree, 1, and which have the same column degree, amongst the fifth to twelfth column (variable node 5 to variable node 12) corresponding to the parity bits of the parity check matrix shown in FIG. 2.

However, the number of padding bits to pad in padding section 205 is two, while the number of columns to extract (the number of variable nodes holding connections with the same number of check nodes) is four, as shown in FIG. 2.

Then, padding section 205 extracts the parity bit positions to be padded candidates in order from the parity bit position corresponding to the variable node connected with the check node having the largest row degree in the parity check matrix (i.e. a parity bit position corresponding to the variable node connected with the check node holding connections with the largest number of variable nodes).

That is, padding section 205 compares the row degrees of the rows in which 1s are located amongst the ninth to twelfth column of the parity check matrix shown in FIG. 2. That is, padding section 205 compares row degree 3 of the fifth row in which a 1 is located in the ninth column (i.e. the number of connections, 3, with variable nodes in check node 5 which variable node 9 is connected with), row degree 4 of the sixth row in which a 1 is located in the tenth column (i.e. the number of connections, 4, with variable nodes in check node 6 which variable node 10 is connected with), row degree 2 of the seventh row in which a 1 is located in the eleventh column (i.e. the number of connections, 2, with variable nodes in check node 7 which variable node 11 is connected with), and row degree 2 of the eighth row in which a 1 is located in the twelfth column (i.e. the number of connections, 2, with variable nodes in check node 8 which variable node 12 is connected with). That is, padding section 205 compares the number of connections with variable nodes between check nodes connected with each variable node amongst variable node 9 to variable node 12 in the Tanner graph shown in FIG. 3. Then, padding section 205 extracts the parity bit positions to be padded candidates in order from the column corresponding to the largest row degree (from the variable node connected with the check node holding connections with the largest number of variable nodes).

Consequently, the order of priority in the parity bit positions to pad padding bits from the ninth to twelfth column (variable node 9 to variable node 12) is that, as shown in FIG. 2, the tenth column (variable node 10) is the first, the ninth column (variable node 10) the second, the eleventh column (variable node 11) and twelfth column (variable node 12) the third.

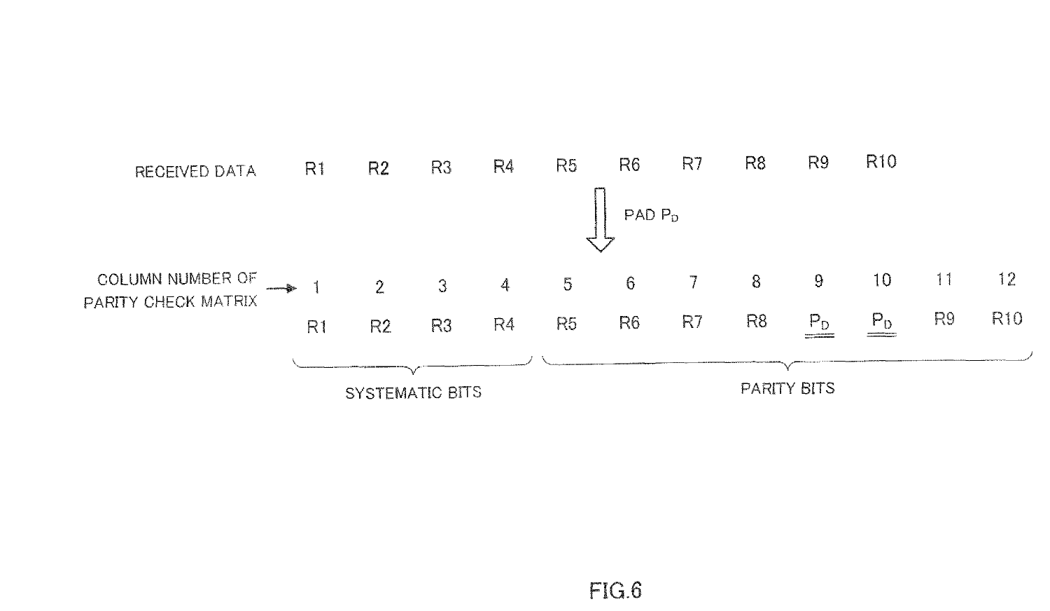

Then, given that the number of padding bits to pad is two, padding section 205 pads two padding bits P_{D} in the same positions as the parity bit positions corresponding to the tenth column (variable node 10) and the ninth column (variable node 9), that is, pads two padding bits P_{D} between the eighth bit R8 and the ninth bit R9 in an 10-bit received data composed of ten bits, R1 to R10, according to the order of priority of padding, as shown in FIG. 6. By this means, R9 and R10 are shifted and arranged to the eleventh bit and twelfth bit. Here, the parity bit positions in which padding bits P_{D} are padded match the positions of parity bits P5 and P6 punctured in radio communication apparatus 100 (FIG. 1) of the transmitting side.

In this way, padding section 205 specifies the padding bit positions to pad padding bits, based on the same parity check matrix as used in puncturing section 102 in radio communication apparatus 100 of the transmitting side. By this means, even when radio communication apparatus 100 of the transmitting side does not report the parity bit positions punctured in radio communication apparatus 100 of the transmitting side, padding section 205 can nevertheless acquire 12-bit data having the same data length (i.e. received data after padding) as the LDPC codeword generated in radio communication apparatus 100 of the transmitting side.

In this way, according to the present embodiment, in a case where there are a plurality of parity bit positions having the same column degree in a parity check matrix, padding bits are padded in order from the same positions as the parity bit positions corresponding to the variable node connected with the check node having the largest row degree in the parity check matrix. By this means, the ratio of the number between variable nodes to pad the padding bits without correlation with punctured parity bits and the number of variable nodes connected via the cheek nodes is low, so that it is possible to minimize the degradation of effect of updating likelihoods and perform LDPC decoding. Therefore, it is possible to minimize the degradation of error rate performances due to puncturing.

Further, according to the present embodiment, the radio communication apparatus of the receiving side is able to specify the parity bit positions to pad padding bits, even when the radio communication apparatus of the transmitting side does not report the parity bit positions to puncture, and therefore the radio communication apparatus of the receiving side can nevertheless perform LDPC decoding that minimizes the degradation of error rate performances due to puncturing, without increasing overhead with report information.

### Embodiment 2

A case will be explained with the present embodiment below where there are a plurality of parity bits having the same column degree and row degree in a parity check matrix.

Now, the operations of puncturing section 102 according to the present embodiment will be explained below.

Systematic bits are transmission bits themselves, while parity bits are redundant bits. Therefore, the degradation of error rate performances is more significant in the case of little effect of updating likelihoods in variable nodes corresponding to systematic bits than corresponding to parity bits. That is, it is preferable to maintain the effect of updating likelihoods significantly for variable nodes corresponding to systematic bits.

Further, when parts of variable nodes are punctured, the degradation of the effect of updating likelihoods in variable nodes corresponding to systematic bits is less, due to the fact that likelihood of variable nodes to puncture cannot be used at a check node holding connections with a smaller number of variable nodes corresponding to systematic bits.

Then, in a case where there are a plurality of parity bits having the same row degree and column degree, puncturing section 102 punctures the parity bits in order from the parity bit corresponding to the variable node connected with the check nodes holding connections with the smallest number of variable nodes corresponding to systematic bits.

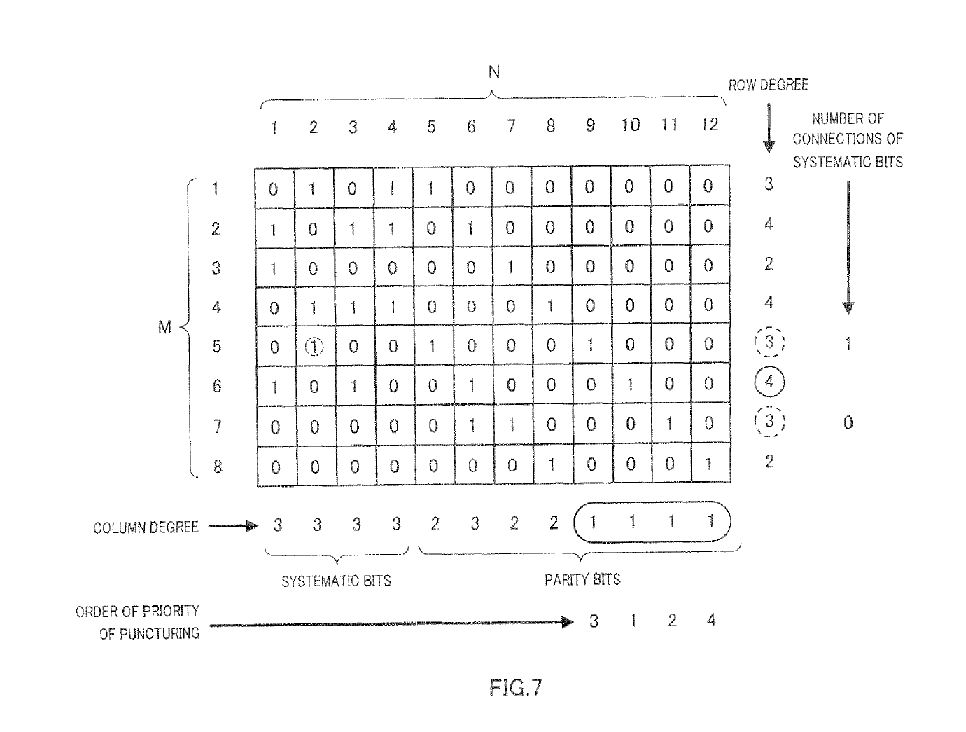

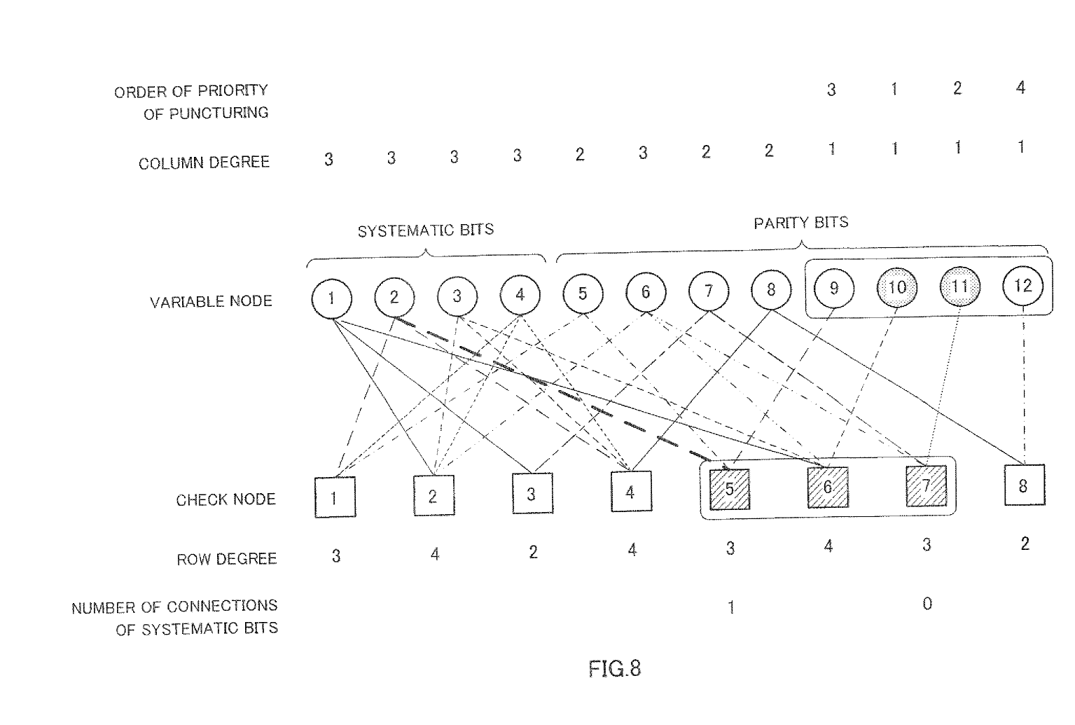

Now, a specific explanation will be given below. With the following explanation, LDPC encoding is performed using the parity check matrix shown in FIG. 7 instead of the parity check matrix in FIG. 2. FIG. 8 shows a Tanner graph corresponding to the parity check matrix in FIG. 7.

Similar to Embodiment 1, puncturing section 102 first extracts parity bits corresponding to the ninth to twelfth column (variable node 9 to variable node 12) as punctured candidates based on the parity check matrix shown in FIG. 7. The order of priority in puncturing at this time is that tenth column is the first, the ninth column and eleventh column the second, and twelfth column the third.

However, while the number of parity bits to puncture in puncturing section 102 is two, the number of columns of the first priority is one, the tenth column, and the number of columns of the second priority is two, the ninth column and the eleventh column, and therefore it is necessary to determine which of the ninth column and eleventh column to make the punctured candidate.

Then, puncturing section 102 extracts the parity bits to be punctured candidates in order from the parity bit corresponding to the variable node connected with the check node holding connections with the smallest number of variable nodes corresponding to systematic bits. That is, puncturing section 102 compares the number of connections with variable node 1 to variable node 4 corresponding to systematic bits between check nodes, amongst variable node 9 to variable node 11 in the Tanner graph shown in FIG. 8. The check node which variable node 9 is connected with is check node 5, and check node 5 is connected with variable node 2 amongst variable node 1 to variable node 4. The check node which variable node 11 is connected with is check node 7, and check node 7 is not connected with any valuable node amongst variable node 1 to variable node 4. Consequently, puncturing section 102 compares the number of connections, 1, with the variable nodes corresponding to systematic bits in check node 5 which variable node 9 is connected with and the number of connection, 0, with the variable nodes corresponding to systematic bits in check node 7 which variable node 11 is connected with.

Then, puncturing section 102 extracts the parity bits to be punctured candidates in order from the variable node connected with the check node holding connections with the smallest number of systematic bits. Consequently, puncturing section 102 makes variable node 11 a punctured candidate of a higher priority than variable node 9. Consequently, as shown in FIG. 8, the order of priority in puncturing for parity bits is that variable node 10 (tenth column) is the first, variable node 11 the second, variable node 9 the third and variable node 12 the fourth.

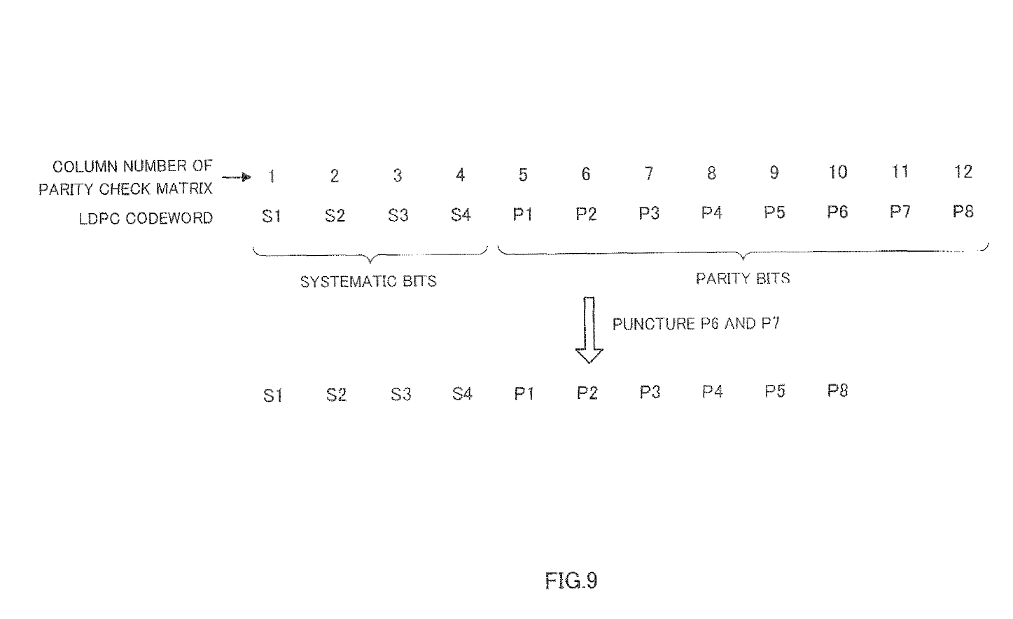

Then, given that the number of parity bits to puncture is two, puncturing section 102 punctures parity bit P6 corresponding to variable node 10 and parity bit P7 corresponding to variable node 11 in a 12-bit LDPC codeword composed of four systematic bits of S1 to S4 and eight parity bits of P1 to P8, according to the order of priority of puncturing, as shown in FIG. 9. By this means, puncturing section 102 can obtain a 10-bit LDPC codeword composed of four systematic bits of S1 to 84 and six parity bits of P1, P2, P3, P4, P5 and P8.

Further, padding section 205 of radio communication apparatus 200 (FIG. 5) of the receiving side specifies the parity bit positions to pad the padding bits in the same method as in puncturing section 102.

In this way, according to the present embodiment, in the case where there are a plurality of parity bits having the same column degree and row degree in a parity check matrix, parity bits are punctured in order from the parity bit corresponding to the variable node connected with the check nodes holding connections with the smallest number of variable nodes corresponding to systematic bits. By this means, it is possible to reduce the number of systematic bits connected with variable nodes to puncture via check nodes, and minimize the degradation of effect of updating likelihoods for systematic bits. Therefore, it is possible to minimize the degradation of error rate performances due to puncturing even when there are a plurality of parity bits having the same column degree and row degree in a parity check matrix.

Embodiments of the present invention have been explained.

Further, although cases have been explained with the embodiments where the present invention is implemented in a FDD (Frequency Division Duplex) system, the present invention may be implemented in a TDD (Time Division Duplex) system. In the case of TDD system, the correlation between uplink channel characteristics and downlink channel characteristics is very high, so that radio communication apparatus 100 of the transmitting side can estimate received quality in radio communication apparatus 200 of the receiving side using signals from radio communication apparatus 200 of the receiving side. Therefore, in the case of TDD system, radio communication apparatus 200 of the receiving side may not report channel quality by CQI and radio communication apparatus 100 of the transmitting side may estimate channel quality.

Further, the parity check matrix shown in FIG. 2 is an example, and a parity check matrix utilized to implement the present invention is not limited to the parity check matrix shown in FIG. 2.

Further, the coding rate set in control section 110 of radio communication apparatus 100 of the transmitting side is not limited to coding rates to be determined according to channel quality, and, may be a fixed rate.

Although cases have been explained with the embodiments where, upon selecting parity bits to puncture, the steps are conducted in order of selecting the parity bit positions of smaller column degrees as the first stage and selecting the parity bit positions of larger row degrees as the second stage, with the present invention, the steps may be conducted in order of selecting the parity bit positions of larger row degrees as the first stage, and selecting the parity bit positions of smaller column degrees as the second stage, that is, the steps may be conducted in reverse order.

Further, although, with the present embodiments, SINR is estimated as channel quality, the SNR, SIR, CINR, received power, interference power, bit error rate, throughput, MCS (Modulation and Coding Scheme) that achieves a predetermined error rate, and so on may be estimated as channel quality. Further, a CQI may be referred to as “CSI (Channel State Information).”

Further, in mobile communication systems, radio communication apparatus 100 of the transmitting side may be provided in a radio communication base station apparatus and radio communication apparatus 200 of the receiving side may be provided in a radio communication mobile station apparatus. Further, radio communication apparatus 100 of the transmitting side may be provided in a radio communication mobile station apparatus and radio communication apparatus 200 of the receiving side may be provided in a radio communication base station apparatus. By this means, it is possible to realize a radio communication base station apparatus and radio communication mobile station apparatus providing an advantage as described above.

Further, a radio communication mobile station apparatus may be referred to as a “UE,” and a radio communication base station apparatus may be referred to as a “Node B.”

Further, although cases have been described with the above embodiment as examples where the present invention is configured by hardware, the present invention can also be realized by software.

Each function block employed in the description of each of the aforementioned embodiments may typically be implemented as an LSI constituted by an integrated circuit. These may be individual chips or partially or totally contained on a single chip. “LSI” is adopted here but this may also be referred to as “IC,” “system LSI,” “super LSI,” or “ultra LSI” depending on differing extents of integration.

Further, the method of circuit integration is not limited to LSIs, and implementation using dedicated circuitry or general purpose processors is also possible. After LSI manufacture, utilization of a programmable FPGA (Field Programmable Gate Array) or a reconfigurable processor where connections and settings of circuit cells within an LSI can be reconfigured is also possible.

Further, if integrated circuit technology comes out to replace LSIs as a result of the advancement of semiconductor technology or a derivative other technology, it is naturally also possible to carry out function block integration using this technology. Application of biotechnology is also possible.

The disclosure of Japanese Patent Application No. 2007-022031, filed on Jan. 31, 2007, including the specification, drawings and abstract, is incorporated herein by reference in its entirety.

### INDUSTRIAL APPLICABILITY

The present invention is applicable to, for example, mobile communication systems.

1. A radio communication apparatus of a transmitting side comprising:
an encoding section that performs low density parity check encoding for a transmission bit sequence using a parity check matrix, to acquire a codeword composed of systematic bits and parity bits; and
a puncturing section that punctures, in the codeword, the parity bits in order from a parity bit of a smallest column degree in the parity check matrix, and, when there are a plurality of parity bits of a same column degree, punctures the parity bits in order from the parity bit corresponding to a variable node connected with a check node of a largest row degree in the parity check matrix.

2. The radio communication apparatus according to claim 1, wherein the puncturing section punctures parity bits in a number to be determined based on a difference between a first coding rate in the low density parity check encoding and a second coding rate according to channel quality.

3. The radio communication apparatus according to claim 1, wherein, when there are the plurality of parity bits of the same column degree and the same row degree, the puncturing section punctures the parity bits in order from a parity bit corresponding to a variable node connected with a check node holding connections with a smallest number of the variable nodes corresponding to the systematic bits.

4. A radio communication apparatus of a receiving side comprising:
a padding section that pads, in received data, padding bits in order from same position as parity bit position of a smallest column degree in a parity check matrix for low density parity check encoding, and, when there are a plurality of parity bits of a same column degree, pads the padding bits in order from the same position as the parity bit position corresponding to a variable node connected with a check node of the largest row degree in the parity check matrix; and
a decoding section that performs low density parity check decoding using the parity check matrix for padded received data, to acquire a decoded bit sequence.

5. The radio communication apparatus according to claim 1, wherein the radio communication apparatus comprises a radio communication base station apparatus or a radio communication mobile station apparatus.

6. The radio communication apparatus according to claim 4, wherein the radio communication apparatus comprises a radio communication base station apparatus or a radio communication mobile station apparatus.

7. A puncturing method in a codeword composed of systematic bits and parity bits and acquired by low density parity check encoding using a parity check matrix, the method comprising:
in the codeword, puncturing the parity bits in order from a parity bit of a smallest column degree in the parity check matrix, and, when there are a plurality of parity bits of a same column degree, punctures the parity bits in the order from the parity bit corresponding to a variable node connected with a check node of a largest row degree in the parity check matrix.
